(19) United States
(12) Patent Application Publication
(10) Pub. No.: US 2026/0189206 A1
(43) Pub. Date: Jul. 2, 2026

(54) Signal Distribution using Passive Network and Multi-Dimensional Impedance Tuning

(71) Applicant: International Business Machines Corporation, Armonk, NY (US)

(72) Inventors: Dereje YILMA, Rochester, MN (US); Sudipto CHAKRABORTY, Plano, TX (US); Pat ROSNO, Rochester, MN (US); Bodhisatwa SADHU, Peekskill, NY (US)

(21) Appl. No.: 18/982,551

(22) Filed: Dec. 16, 2024

(51) Int. Cl. H03H 7/38; H03F 3/45; H03H 7/06

(52) U.S. Cl. CPC H03H 7/383; H03H 7/06; H03F 3/45632

(57) ABSTRACT

A device comprises an input stage, a signal distribution network comprising a plurality of passive elements, and a plurality of output stages coupled to the signal distribution network. The input stage is configured to drive a signal onto the signal distribution network. The signal distribution network is configured to distribute the signal to the plurality of output stages. Each output stage of the plurality of output stages comprises a variable resistance element and a variable reactance element, for tuning a complex input impedance of the output stage to obtain a signal transfer characteristic for transferring the signal from the input stage to the output stage over the signal distribution network.

### BACKGROUND

This disclosure relates generally to signal distribution systems and, in particular, to techniques for distributing signals in a system which comprises a large array of signal channels. Modern communication systems and computing systems, such as quantum computing systems, artificial intelligence (AI) systems, machine learning (ML) systems, Internet-of-Things (IoT) systems, millimeter Wave (mmWave) communications systems such as fifth-generation (5G) and sixth-generation (6G) wireless communication systems, high speed input/output (I/O) systems, etc., comprise large arrays of signal channels that are driven by clock signals which are generated by a central clock element (e.g., phase-locked loop (PLL)) and/or clock buffers). The clock signals are distributed to the array of signal channels using a signal distribution system to, e.g., enable phase synchronized operation. Typically, signal distribution systems consume a significant amount of power, and suffer from low power efficiency. In addition, signal distribution systems can suffer from degraded performance due to, e.g., increased signal jitter and the injection of noise into the clock distribution paths, which degrades the clock signals.

### SUMMARY

Exemplary embodiments of the disclosure include signal distribution systems and techniques for implementing power-efficient signal distribution using passive distribution networks and multi-dimensional impedance tuning.

An exemplary embodiment includes a device which comprises an input stage, a signal distribution network comprising a plurality of passive elements, and a plurality of output stages coupled to the signal distribution network. The input stage is configured to drive a signal onto the signal distribution network. The signal distribution network is configured to distribute the signal to the plurality of output stages. Each output stage of the plurality of output stages comprises a variable resistance element and a variable reactance element, for tuning a complex input impedance of the output stage to obtain a signal transfer characteristic for transferring the signal from the input stage to the output stage over the signal distribution network.

Another exemplary embodiment includes a system which comprises a plurality of signal channels, a signal generator which is configured to generate a signal, and a signal distribution system which is configured to distribute the signal to the plurality of signal channels. The signal distribution system comprises an input stage, a signal distribution network comprising a plurality of passive elements, and a plurality of output stages. Each output stage is coupled to the signal distribution network and coupled to a respective signal channel of the plurality of signal channels. The input stage is configured to drive the signal onto the signal distribution network. The signal distribution network is configured to distribute the signal to the plurality of output stages. Each output stage of the plurality of output stages comprises a variable resistance element and a variable reactance element, for tuning a complex input impedance of the output stage to obtain a signal transfer characteristic for transferring the signal from the input stage to the output stage over the signal distribution network.

Another exemplary embodiment includes a method which comprises: driving, by an input stage, a signal onto a signal distribution network comprising a plurality of passive elements; distributing the signal over the signal distribution network to a plurality of output stages; and tuning a complex input impedance of a given output stage of the plurality of output stages by adjusting at least one of a variable resistance element and a variable reactance element of the given output stage to obtain a signal transfer characteristic for transferring the signal from the input stage to the given output stage over the signal distribution network.

Other embodiments will be described in the following detailed description of exemplary embodiments, which is to be read in conjunction with the accompanying figures.

### BRIEF DESCRIPTION OF THE DRAWINGS

FIG. 1 schematically illustrates a multi-channel system which comprises a signal distribution system according to an exemplary embodiment of the disclosure.

FIG. 2A schematically illustrates a signal distribution system according to another exemplary embodiment of the disclosure.

FIG. 2B schematically illustrates a signal distribution network according to another exemplary embodiment of the disclosure.

FIG. 3 schematically illustrates an impedance tuning stage according to an exemplary embodiment of the disclosure.

FIG. 4 schematically illustrates a signal distribution network according to another exemplary embodiment of the disclosure.

FIG. 5 schematically illustrates a peak detector which can be implemented in a signal distribution system, according to an exemplary embodiment of the disclosure.

FIG. 6 illustrates a flow diagram of a method for calibrating an impedance tuning stage of a signal distribution system, according to an exemplary embodiment of the disclosure.

FIG. 7 schematically illustrates a buffer circuit which can be implemented in a signal channel of a multi-channel system, according to an exemplary embodiment of the disclosure.

FIG. 8 schematically illustrates a quantum computing system which implements a signal distribution system to distribute local oscillator signals to a plurality of signal channels, according to an exemplary embodiment of the disclosure.

FIG. 9 schematically illustrates an exemplary computing environment which is configured to execute program instructions for performing impedance tuning calibration operations for a signal distribution system, according to an exemplary embodiment of the disclosure.

### DETAILED DESCRIPTION

Exemplary embodiments of the disclosure will now be described in further detail with regard signal distribution systems and techniques for implementing power-efficient signal distribution using passive distribution networks and multi-dimensional impedance tuning.

An exemplary embodiment includes a device which comprises an input stage, a signal distribution network comprising a plurality of passive elements, and a plurality of output stages coupled to the signal distribution network. The input stage is configured to drive a signal onto the signal distribution network. The signal distribution network is configured to distribute the signal to the plurality of output stages. Each output stage of the plurality of output stages comprises a variable resistance element and a variable reactance element, for tuning a complex input impedance of the output stage to obtain a signal transfer characteristic for transferring the signal from the input stage to the output stage over the signal distribution network.

Another exemplary embodiment includes a system which comprises a plurality of signal channels, a signal generator which is configured to generate a signal, and a signal distribution system which is configured to distribute the signal to the plurality of signal channels. The signal distribution system comprises an input stage, a signal distribution network comprising a plurality of passive elements, and a plurality of output stages. Each output stage is coupled to the signal distribution network and coupled to a respective signal channel of the plurality of signal channels. The input stage is configured to drive the signal onto the signal distribution network. The signal distribution network is configured to distribute the signal to the plurality of output stages. Each output stage of the plurality of output stages comprises a variable resistance element and a variable reactance element, for tuning a complex input impedance of the output stage to obtain a signal transfer characteristic for transferring the signal from the input stage to the output stage over the signal distribution network.

In another exemplary embodiment, which may be combined with one or more of the embodiments of the preceding paragraphs, the signal transfer characteristic comprises at least one of a maximum power transfer, a maximum voltage transfer, and a maximum current transfer.

In another exemplary embodiment, which may be combined with one or more of the embodiments of the preceding paragraphs, each output stage of the plurality of output stages comprises an attenuation circuit that is configured to scale an amplitude of the signal output from the output stage.

In another exemplary embodiment, which may be combined with one or more of the embodiments of the preceding paragraphs, each output stage of the plurality of output stages comprises a buffer circuit and a resonant tank circuit coupled to an output of the buffer circuit. The resonant tank circuit comprises the variable resistance element and the variable reactance element for tuning the complex input impedance of the output stage.

In another exemplary embodiment, which may be combined with one or more of the embodiments of the preceding paragraphs, the variable reactance element comprises a variable capacitor.

In another exemplary embodiment, which may be combined with one or more of the embodiments of the preceding paragraphs, the signal is distributed in current mode over the signal distribution network, and the buffer circuit comprises a current buffer which receives the signal as a current and outputs the signal as a current to the resonant tank circuit.

In another exemplary embodiment, which may be combined with one or more of the embodiments of the preceding paragraphs, the current buffer comprises a first transistor in a common gate amplifier configuration, and a second transistor connected in parallel with the first transistor. The second transistor comprises an adjustable width transistor structure which comprises multiple transistor segments coupled in parallel. The width of the second transistor is adjusted in response to a control signal to scale an amplitude of the signal that is output from the current buffer to the resonant tank circuit.

In another exemplary embodiment, which may be combined with one or more of the embodiments of the preceding paragraphs, the input stage comprises a linear transconductance amplifier which is configured to receive a voltage signal and output a current signal as the signal to drive the signal distribution network, and a programmable common mode input voltage.

In another exemplary embodiment, which may be combined with one or more of the embodiments of the preceding paragraphs, the signal distribution network comprises an H-tree topology of passive transmission lines which provide respective transmission line paths from the input stage to each output stage of the plurality of output stages.

In another exemplary embodiment, which may be combined with one or more of the embodiments of the preceding paragraphs, each transmission line path has an electrical length that is a multiple of one-half wavelength of wavelength of the signal that is distributed over the signal distribution network.

In another exemplary embodiment, which may be combined with one or more of the embodiments of the preceding paragraphs, The device or system further comprises a peak detector circuit and a calibration system. The peak detector circuit is coupled to at least one output stage of the plurality of output stages, and configured to detect one of: a maximum output power; maximum output voltage; and a maximum output current, of the at least one output stage. The calibration system coupled to the peak detector circuit, and configured to generate a control signal to tune the complex input impedance of the at least one output stage based at least in part on one of: the detected maximum output power; the detected maximum output voltage; and the detected maximum output current, of the at least one output stage.

Another exemplary embodiment includes a method which comprises: driving, by an input stage, a signal onto a signal distribution network comprising a plurality of passive elements; distributing the signal over the signal distribution network to a plurality of output stages; and tuning a complex input impedance of a given output stage of the plurality of output stages by adjusting at least one of a variable resistance element and a variable reactance element of the given output stage to obtain a signal transfer characteristic for transferring the signal from the input stage to the given output stage over the signal distribution network.

In another exemplary embodiment, which may be combined with one or more of the embodiments of the preceding paragraphs, the signal transfer characteristic comprises at least one of a maximum power transfer, a maximum voltage transfer, and a maximum current transfer.

In another exemplary embodiment, which may be combined with one or more of the embodiments of the preceding paragraphs, a method further comprises tuning an electrical length of at least one passive transmission line of the signal distribution network, in a transmission line path from the input stage to the given output stage, to obtain the signal transfer characteristic for transferring the signal from the input stage to the given output stage over the signal distribution network.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), superconducting elements such as superconducting quantum bits, programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

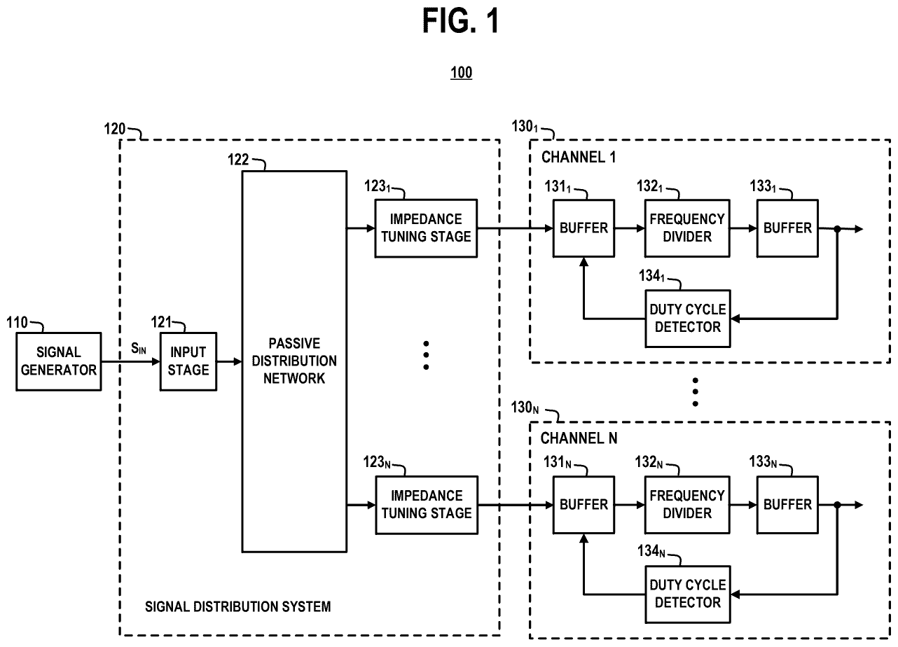

FIG. 1 schematically illustrates a multi-channel system comprising a signal distribution system according to an exemplary embodiment of the disclosure. In particular, FIG. 1 schematically illustrates a multi-channel system 100 which comprises a signal generator 110, a signal distribution system 120, and a plurality of signal channels 130₁, . . . , 130_{N} (generally, signal channels 130). The signal distribution system 120 comprises an input stage 121, a passive distribution network 122, and a plurality of impedance tuning stages 123₁, . . . , 123_{N}. In some embodiments, the signal channels 130₁, . . . , 130_{N} each comprise a respective first buffer 131₁, . . . , 131_{N}, a respective frequency divider 132₁, . . . , 132_{N}, a respective second buffer 133₁, . . . , 133_{N}, and a respective duty cycle detector 134₁, . . . , 134_{N}. While not specifically shown in FIG. 1, each signal channel 130₁, . . . , 130_{N} would comprise additional components to implement functions associated with a given communications system (e.g., wireless communications system) or computing system (e.g., quantum computing system).

The signal generator 110 is configured to generate a signal S_{IN} that is distributed by the signal distribution system 120 to the plurality of signal channels 130₁, . . . , 130_{N}. The signal S_{IN} can be any type of signal which is suitable for performing functions of the given communications system or computing system. For example, in some embodiments, the signal generator 110 comprises clock signal generator, such as a phase-lock loop (PLL) circuit or clock buffer circuit, which is configured to generate a clock signal that is distributed over the signal distribution system 120 to the plurality of signal channels 130 to implement synchronized operations of the given communications system or computing system. In other embodiments, the signal generator 110 is configured to generate a local oscillator (LO) signal that is to be distributed to the plurality of signal channels 130 and applied to mixers (e.g., quadrature mixers) which perform heterodyning operations (frequency up-conversion or frequency down-conversion operations) to implement functions of the given communications system or computing system.

In other embodiments, the signal generator 110 is configured to generate an information signal (e.g., a signal which carries information content) that is distributed over the signal distribution system 120 to the plurality of signal channels 130 to implement functions of the given communications system or computing system. In this regard, it is to be noted that the term “signal” as used herein broadly refers to any type of signal that is distributed over the signal distribution system 120 to multiple signal channels 130₁, . . . , 130_{N}, including, but not limited to clock signals, LO signals, information signals, etc.

The signal distribution system 120 implements a passive transmission line distribution network in conjunction with narrowband tuning of load impedances, to distribute a given signal S_{IN} (e.g., clock signal) to the array of signal channels 130₁, . . . , 130_{N} of a given computing system or communications system, in a power-efficient manner. The input stage 121 serves as a signal receiver that is configured to receive the input signal S_{IN} (e.g., a clock signal or an LO signal), which is output and transmitted from the signal generator 110, and to drive the input of the passive distribution network 122. The passive distribution network 122 comprises passive transmission lines, which are arranged in a given distribution network topology (e.g., H-tree of passive transmission lines), to distribute the input signal S_{IN} to multiple consumption points, where each consumption point comprises a given impedance tuning stage of the plurality of impedance tuning stages 123₁, . . . , 123_{N}, which is coupled to an input of a respective one of the signal channels 130₁, . . . , 130_{N} (Channel 1, . . . , Channel N).

The input stage 121 serves as a buffer and driver stage which is configured to (i) isolate the signal generator 110 from the passive distribution network 122, and (ii) drive the passive distribution network 122 with a signal (voltage signal or current signal) that corresponds to the input signal S_{IN}. In some embodiments, the input stage 121 comprises a linear transconductance driver stage (e.g., a common source amplifier stage) which can be configured as an amplifier (e.g., class A, AB, B, or C amplifier). For differential signal embodiments, the input stage 121 can be implemented using a transistor pair in a pseudo differential configuration. Moreover, in some embodiments, the input stage 121 is configured to have a programmable input common mode voltage (V_{CM}). Further, in some embodiments, the input stage 121 is implemented with transistors having reconfigurable sizes. For example, the transistors of the input stage 121 can be implemented using a variable-width transistor structure that is configured and controlled using known techniques to vary the effective gate width of the transistor structure and, thus, enable transconductance (gₘ) tuning,

$${ℊ}_{m} = \frac{Δ {I}_{OUT}}{Δ {V}_{IN}} ,$$

in the input stage 121. In other embodiments, the input stage 121 can be implemented using a switching amplifier stage such as a class D, class F, or inverse-D switching amplifier stage.

The passive distribution network 122 is implemented using a suitable network topology (e.g., H-tree topology) of low-loss transmission lines (e.g., coplanar waveguide (CPW) transmission lines, microstrip transmission lines, etc.). The passive distribution network 122 enables ultra-low-power distribution of signals over a large array of transmission lines with relatively long lengths, e.g., several millimeters or longer, with minimal or insignificant jitter and distortion/noise (as compared to transmission lines having multiple segments connected by active buffers which add noise to signal transmission). In some embodiments, depending on the application, the passive distribution network 122 may comprise transmission lines that are formed of superconducting metallic material and may be disposed in cryogenic temperature environment, in which case the long transmission lines will have extremely low resistance and, thus, have low power dissipation.

Moreover, in some embodiments, the electrical lengths of the transmission line paths of the passive distribution network 122 from source (e.g., input stage 121) to load (e.g., the impedance tuning stages 123₁, . . . , 123_{N}) can be made to be one-half wavelength (or a multiple of one-half wavelengths) of the signal wavelength to enable standing wave formation on the long transmission lines to thereby efficiently transmit and distribute input signals from source to load over the passive distribution network 122. Indeed, minimizing signal losses along a transmission line can be obtained when the source impedance Z_{source} (e.g., output impedance of input stage 121) is the complex conjugate (denoted *) of the load impedance Z_{Load} (e.g., input impedance of a given impedance tuning stage 123). In instances where the source impedance is matched to the load impedance

$$( e . g . , {Z}_{Source} = {Z}_{Load}^{*} )$$

such impedance match will remain when the source and load are connected through a transmission line with an electrical length of one half-wavelength (or a multiple of one half wavelengths) of the signal wavelength using a transmission line irrespective of the characteristic impedance Z₀ of the transmission line.

In the multi-channel system 100, the impedance tuning stages 123₁, . . . , 123_{N} serve as buffers and impedance tunable loads that are coupled to endpoints of the transmission line paths of the passive distribution network 122. In particular, the impedance tuning stages 123₁, . . . , 123_{N} comprises buffers that are configured to isolate the passive distribution network 122 from the signal channels 130₁, . . . , 130_{N}. In addition, the impedance tuning stages 123₁, . . . , 123_{N} are configured to enable complex impedance tuning (e.g., tuning of a real impedance (e.g., resistance) and/or an imaginary impedance (e.g. reactance)) to tune the load impedance (e.g., input impedance of a given impedance tunning stage) to a given value to thereby obtain a desired signal transfer characteristic for transferring a signal from source (input stage) to load (impedance tuning stage) over the passive distribution network 122. It is to be noted that the term “signal transfer characteristic” refers to a condition of obtaining, e.g., (i) a maximum power transfer, (ii) a minimal signal reflection, (iii) a maximum voltage transfer, or (iv) a maximum current transfer, or any desired signal transfer characteristic to obtain a desired power efficiency for transferring signals from source to load, tuning the complex input impedance of the impedance tuning stages 123₁, . . . 123_{N} (and possibly other components of the signal distribution system, as discussed below).

More specifically, in some embodiments, to obtain a signal transfer characteristic for maximum power transfer, the complex input impedances Z_{Load} of the impedance tuning stages 123₁, . . . , 123_{N} can be tuned to obtain a maximum transfer of power from source to load over the passive distribution network 122 by tuning the complex input impedances Z_{Load} of the impedance tuning stages 123₁, . . . , 123_{N} to match the complex conjugate of the source output impedance Z_{source} (e.g., output impedance of input stage 121). Moreover, for voltage mode transmission of voltage signals over the passive distribution network 122 from source to load, maximum voltage transfer is obtained when the source has a relatively low output impedance, and the load has a relatively high input impedance (i.e., Z_{Load}>>Z_{source}). On the other hand, for current mode transmission of current signals over the passive distribution network 122 from source to load, current matching is obtained (e.g., source current≈load current) when the source has a relatively high output impedance, and the load has a relatively low input impedance (i.e., Z_{Load}<<Z_{source}). In other embodiments, the complex input impedances Z_{Load} of the impedance tuning stages 123₁, . . . , 123_{N} can be tuned to modulate the signal transmission and distribution through impedance matched or impedance unmatched systems, as desired, depending on reliability requirements and overall length of the transmission line paths of the passive distribution network 122 to obtain a desired amount of power consumption and power efficient signaling.

FIG. 1 illustrates an exemplary embodiment in which the multi-channel system 100 comprises a communications system or computing system, in which the signal distribution system 120 is configured to distribute clock signals or LO signals to the signal channels 130₁, . . . , 130_{N}. For example, the first buffers 131₁, . . . , 131_{N} are configured to provide isolation and drive the respective frequency dividers 132₁, . . . , 132_{N}. The respective frequency dividers 132₁, . . . , 132_{N} (or clock dividers) are configured to receive an input signal of frequency f_{IN}, and generate an output signal of frequency f_{OUT}, where f_{OUT}=f_{IN}/N, where N is an integer. For example, in some embodiments, the frequency dividers 132₁, . . . , 132_{N} comprises quadrature frequency dividers (where N=2) which receive an LO signal with a frequency 2*f_{LO}, and generate quadrature LO signals, including an in-phase LO signal (LO_I) and a quadrature-phase LO signal (LO_Q), where LO_I and LO_Q have a same frequency of f_{LO}, but differ in phase by 90 degrees. For example, by convention, the LO_I signal is a cosine waveform, and the LO_Q signal component is a sine waveform, wherein the LO_I and LO_Q signals have the same LO frequency. In the context of a quantum computing system, the frequency f_{LO} of the quadrature LO signals corresponds to a transition frequency f₀₁ of a qubit which is driven by the given signal channel.

The second buffers 133₁, . . . , 133_{N} are configured to provide isolation and drive the outputs of the respective frequency dividers 132₁, . . . , 132_{N}. The duty cycle detectors 134₁, . . . , 134_{N} are coupled to outputs of respective ones of the second buffers 133₁, . . . , 133_{N}. In some embodiments, in the context of clock signal or LO signal distribution, the duty cycle detectors 134₁, . . . , 134_{N} are configured to detect for the presence of duty cycle error/distortion of the signals that are output from the second buffers 133₁, . . . , 133_{N}, and generate control signals that are applied to actuation mechanisms in the first buffers 131₁, . . . , 131_{N} to correct duty cycle errors. The duty cycle detectors 134₁, . . . , 134_{N} are implemented to ensure that the clock or LO signals that are output from the second buffers 133₁, . . . , 133_{N} have duty cycles of 50%. The duty cycle detectors 134₁, . . . , 134_{N} and associated actuation mechanisms for calibrating/correcting duty cycle errors can be implemented using suitable circuit architectures and techniques that are well-known to those of ordinary skill in the art.

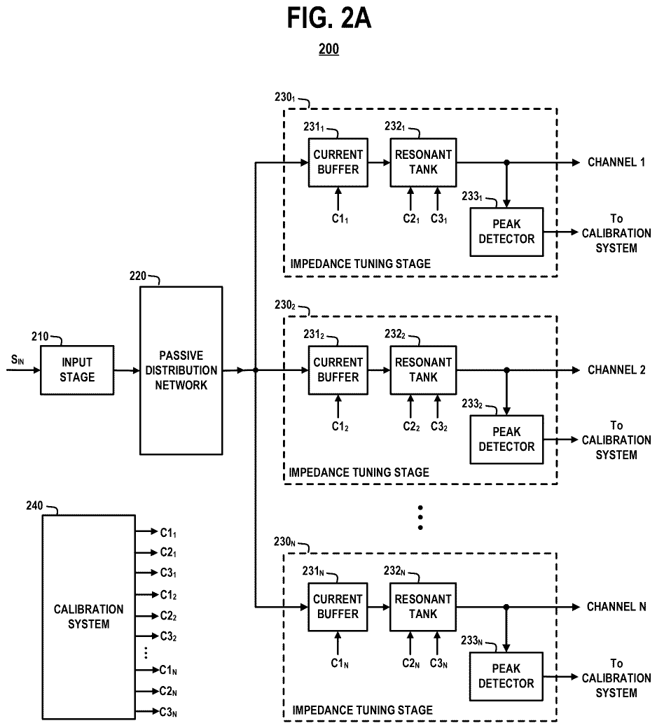

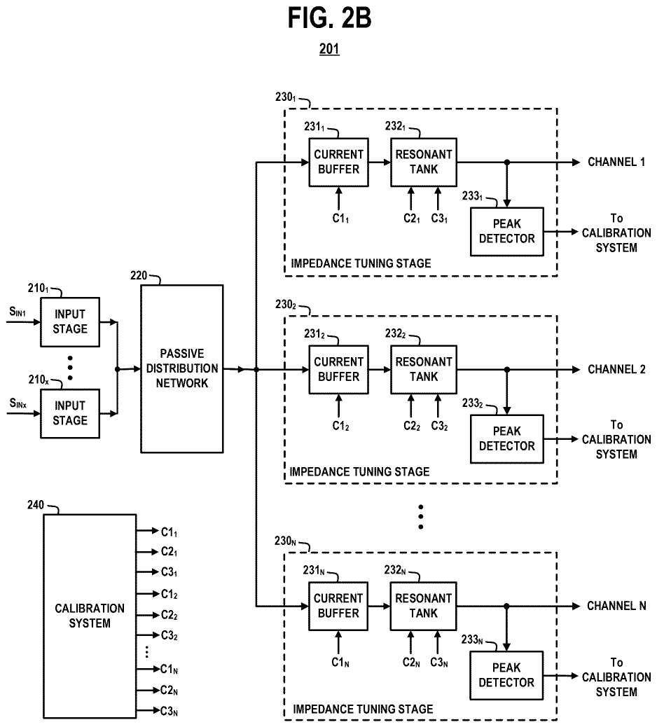

Next, FIG. 2A schematically illustrates a signal distribution network according to an exemplary embodiment of the disclosure. In particular, FIG. 2A schematically illustrates an exemplary embodiment of a signal distribution network 200 which can be utilized to implement the signal distribution system 120 of FIG. 1. The signal distribution network 200 comprises an input stage 210, a passive distribution network 220, a plurality of impedance tuning stages 230₁, 230₂, . . . , 230_{N} (generally, impedance tuning stage or stages 230), and a calibration system 240. In some embodiments, the impedance tuning stages 230₁, 230₂, . . . , 230_{N} each comprise a respective current buffer 231₁, 231₂, . . . , 231_{N}, a respective resonant tank 232₁, 232₂, . . . , 232_{N}, and a respective peak detector 233₁, 233₂, . . . , 233_{N}. The impedance tuning stages 230₁, 230₂, . . . , 230_{N} comprise respective outputs that are coupled to respective signal channels, Channel 1, Channel 2, . . . Channel N.

In some embodiments, the input stage 210 and the passive distribution network 220 implement the same or similar circuit architectures and operating modes as the input stage 121 and the passive distribution network 122 (FIG. 1) as discussed above. The input stage 210 serves as a signal receiver that is configured to receive an input signal S_{IN} (voltage signal) which is transmitted from a signal generator (e.g., PLL circuit) and drive an input of the passive distribution network 220 via current mode transmission to thereby distribute the input signal S_{IN} (current signal) to the inputs of the impedance tuning stages 230₁, 230₂, . . . , 230_{N}.

In the impedance tuning stages 230₁, 230₂, . . . , 230_{N}, the respective current buffers 231₁, 231₂, . . . , 231_{N}, are configured to receive as input the current signals which are transmitted over the passive distribution network 220, and generate output current signals which are input to the respective resonant tanks 232₁, 232₂, . . . , 232_{N}, while providing isolation between the passive distribution network 220 and the resonant tanks 232₁, 232₂, . . . , 232_{N} that load the current buffers 231₁, 231₂, . . . , 231_{N}. In some embodiments, each of the resonant tanks 232₁, 232₂, . . . , 232_{N} comprises a resonator circuit which comprises resistor (R), inductor (L), and capacitor (C) elements that are connected in a given topology to form an RLC resonator circuit. In some embodiments, the resonant tanks 232₁, 232₂, . . . , 232_{N} are configured with R, L and C elements connected in parallel.

In some embodiments, the R and C elements of the resonant tanks 232₁, 232₂, . . . 232_{N} comprise variable resistor devices and variable capacitor devices that are digitally controlled to enable complex impedance tuning of the impedance tuning stages 230₁, 230₂, . . . , 230_{N} and thereby tune the input impedances of the current buffers 231₁, 231₂, . . . , 231_{N}, to modulate the amount of current signal transfer from source (e.g., the input stage 210) to load (impedance tuning stage 230) over the passive distribution network 220. For example, as noted above, the input impedance (load impedance) of the impedance tuning stages 230₁, 230₂, . . . , 230_{N} can be tuned based on the output impedance of the input stage 210 (e.g., via complex conjugate matching) to extract a maximum amount of current from the input stage 210 (e.g., transconductance stage with high output impedance).

In some embodiments, as shown in FIG. 2A, the calibration system 240 is configured to generate control signals (e.g., digital control signals) that are applied to the impedance tuning stages 230₁, 230₂, . . . , 230_{N} to (i) tune the complex input impedances of the impedance tuning stages 230₁, 230₂, . . . , 230_{N} and (ii) adjust the magnitudes of output signals that are generated and output from the impedance tuning stages 230₁, 230₂, . . . , 230_{N}. In some embodiments, the calibration system 240 is implemented using a combination of software (e.g., program execution), hardware (e.g., control logic and circuitry), and/or firmware, to implement various calibration functions, as described herein. For example, in some embodiments, the calibration system 240 is configured to generate a set of first control signals C1₁, C1₂, . . . , C1_{N}, which are applied to the respective current buffers 231₁, 231₂, . . . , 231_{N} to enable scaling (e.g., adjust the output amplitude) of the signals that are output from the impedance tuning stages 230₁, 230₂, . . . , 230_{N}.

Moreover, in some embodiments, the calibration system 240 is configured to generate a set of second control signals C2₁, C2₂, . . . , C2_{N}, and a set of third control signals C3₁, C3₂, . . . , C3_{N}, which are applied to the respective resonant tanks 232₁, 232₂, . . . , 232_{N} to enable tuning of the input impedances of the impedance tuning stages 230₁, 230₂, . . . , 230_{N}. For example, in some embodiments, the second control signals C2₁, C2₂, . . . , C2_{N} are utilized to adjust reactance components of the complex input impedances of the respective impedance tuning stages 230₁, 230₂, . . . , 230_{N}. For example, the second control signals C2₁, C2₂, . . . , C2_{N} are utilized to control variable capacitors of the respective resonant tanks 232₁, 232₂, . . . , 232_{N} to tune the reactance components of the input impedances of the respective impedance tuning stages 230₁, 230₂, . . . , 230_{N}. Moreover, in some embodiments, the third control signals C3₁, C3₂, . . . , C3_{N} are utilized to adjust resistive (real) components of the complex input impedances of the respective impedance tuning stages 230₁, 230₂, . . . , 230_{N}. For example, the third control signals C3₁, C3₂, . . . , C3_{N} are utilized to control variable resistors of the respective resonant tanks 232₁, 232₂, . . . , 232_{N}.

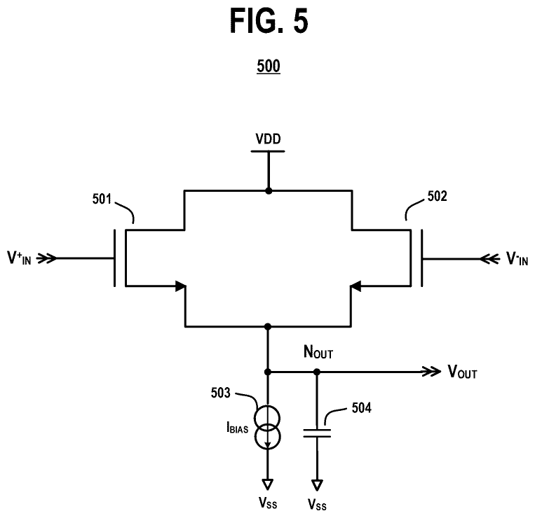

In some embodiments, the peak detectors 233₁, 233₂, . . . , 233_{N} are configured to detect peak (maximum) amplitudes of signals that are output from the respective resonant tanks 232₁, 232₂, . . . , 232_{N}, and output calibration data which represents the detected peak signal amplitudes to the calibration system 240. The calibration data provides an indication as to whether the impedance tuning stages 230₁, 230₂, . . . , 230_{N} have the proper input impedances to obtain the target signal transfer from source to load over the passive distribution network 220 (e.g., maximum power, current, or voltage transfer), and a desired output amplitude. The calibration system 240 utilizes the calibration data to generate the control signals for tuning the impedance tuning stages 230₁, 230₂, . . . , 230_{N}, as needed, to obtain the target signal transfer characteristics from source to load over the passive distribution network 220. An exemplary embodiment of a peak detector will be discussed in further detail below in conjunction with FIG. 5.

In some embodiments, the calibration system 240 is utilized to perform an initial calibration process (e.g., upon start-up) to calibrate the impedance tuning stages 230₁, 230₂, . . . , 230_{N} to have desired input impedances and output signal amplitudes for a given application. Moreover, in some embodiments, the peak detectors 233₁, 233₂, . . . , 233_{N} and the calibration system 240 are utilized during real-time operation to track changes, if any, to the output signals over time as a result of, e.g., temperature variation, and make fine tune adjustments if needed.

Next, FIG. 2B schematically illustrates a signal distribution network according to another exemplary embodiment of the disclosure. In particular, FIG. 2B illustrates an exemplary signal distribution network 201 which is similar to the signal distribution network 200 of FIG. 2A in terms of architecture and modes of operation, except that the signal distribution network 201 comprises a plurality of input stages 210₁, . . . , 210ₓ that are commonly coupled to an input of the passive distribution network 220. The input stages 210₁, . . . , 210ₓ are configured to receive respective input signals S_{IN1}, . . . , S_{INx}, which differ in frequency, amplitude, and/or phase. In this exemplary embodiment, the signal distribution network 201 is configured to distribute each of the different input signals S_{IN1}, . . . , S_{INx} to one or more of the signal channels Channel 1, Channel 2, . . . , Channel N, depending on the desired operating frequency of the given signal channel.

For example, in some embodiments, the number (x) of input stages 210₁, . . . , 210ₓ is the same as the number (N) of signal channels Channel 1, Channel 2, . . . , Channel N, such that the signal distribution network 201 is configured to transmit each input signal S_{IN1}, . . . , S_{INx} to a respective one of the signal channels Channel 1, Channel 2, . . . , Channel N. In other embodiments, the number (x) of input stages 210₁, . . . , 210ₓ is different from the number (N) of signal channels Channel 1, Channel 2, . . . , Channel N, such that the signal distribution network 201 is configured to transmit each input signal S_{IN1}, . . . , S_{INx} to at least two signal channels Channel 1, Channel 2, . . . , Channel N.

The passive distribution network 220 is configured to provide wideband operation over a given frequency range to thereby allow wideband transmission of signals with different frequencies over the passive distribution network 220. The input stages 210₁, . . . , 210ₓ can be selectively activated and deactivated using a timing schedule or time domain multiplexing protocol. A given input stage can be activated and deactivated by controlling gate bias voltages applied to gate terminals of transistor device pairs of the given input stage. The resonant tanks 232₁, 232₂, . . . , 232_{N} of the respective impedance tuning stages 230₁, 230₂, . . . , 230_{N} are tuned via the calibration system 240 to operate at respective target resonant frequencies based on the operating frequencies of the respective signal channels Channel 1, Channel 2, . . . , Channel N. Moreover, as noted above, the current buffers 231₁, 231₂, . . . , 231_{N} of the respective impedance tuning stages 230₁, 230₂, . . . , 230_{N} provide isolation from the narrowband tuned impedances of the respective resonant tanks 232₁, 232₂, . . . , 232_{N}.

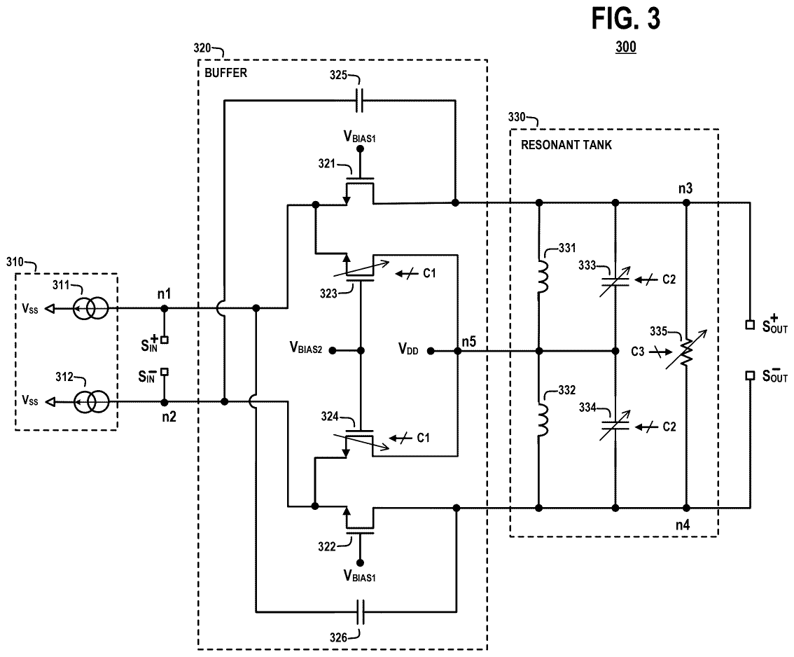

FIG. 3 schematically illustrates an impedance tuning stage according to an exemplary embodiment of the disclosure. In particular, FIG. 3 schematically illustrates an exemplary embodiment of an impedance tuning stage 300 which can be utilized to implement the impedance tuning stages shown in FIGS. 1, 2A and/or 2B. In addition, FIG. 3 illustrates an exemplary embodiment of an impedance tuning stage 300 that can be utilized as an output stage for current mode distribution of signals in the exemplary signal distribution networks disclosed herein. The impedance tuning stage 300 comprises a biasing stage 310, a buffer stage 320, and a resonant tank 330. FIG. 3 illustrates an exemplary embodiment of an impedance tuning stage 300 that can be utilized as an output stage for current mode distribution of differential signals (differential current signals) in the exemplary signal distribution networks disclosed herein. The impedance tuning stage 300 comprises a first input node n1 which receives a first signal

$${S}_{IN}^{+} ( or first current signal {S}_{IN}^{+} )$$

and a second input node n2 which receives a second signal

$${S}_{IN}^{-} ( or second current signal {S}_{IN}^{-} ) ,$$

wherein the first and second signals

$${S}_{IN}^{+} and {S}_{IN}^{-}$$

comprise complementary current signals. The impedance tuning stage 300 comprises output nodes n3 and n4, which output complementary voltage signals

$${S}_{OUT}^{+} and {S}_{OUT}^{-} ,$$

respectively.

The biasing stage 310 comprises a first current source 311 and a second current source 312. The biasing stage 310 provides static bias currents (or quiescent currents) for biasing current mode active devices of the buffer stage 320. The buffer stage 320 is loaded by the resonant tank 330. In some embodiments, such as shown in FIG. 3, the buffer stage 320 comprises a current buffer which comprises a first transistor 321, a second transistor 322, a third transistor 323, a fourth transistor 324, a first capacitor 325, and a second capacitor 326. The resonant tank 330 comprises an RLC circuit comprising a first inductor 331, a second inductor 332, a first variable capacitor 333, a second variable capacitor 334, and a variable resistor 335.

In the buffer stage 320, the first transistor 321 and the second transistor 322 comprise current mode active devices that implement a common-gate amplifiers. In an exemplary embodiment, the first and second transistors 321 and 322 comprise N-type MOSFET devices. The first transistor 321 and the second transistor 322 comprise respective gate terminals that are commonly coupled to a first bias voltage V_{BIAS1}. The first transistor 321 comprises a drain terminal that is coupled to the first output node n3, and a source terminal that is coupled to the first input node n1. The second transistor 322 comprises a drain terminal that is coupled to the second output node n4, and a source terminal that is coupled to the second input node n2. In an exemplary embodiment, the first and second transistors 321 and 322 comprise N-type MOSFET devices.

With the exemplary common-gate amplifier configuration, the source terminal of the first transistor 321 serves as a signal input terminal

$$( which receives the first signal {S}_{IN}^{+} ) ,$$

and the drain terminal of the first transistor 321 serves as a signal output terminal of the common-gate amplifier. Similarly, the source terminal of the second transistor 322 serves as a signal input terminal

$$( which receives the second signal {S}_{IN}^{-} ) ,$$

and the drain terminal of the second transistor 322 serves as a signal output terminal of the common-gate amplifier. The first and second capacitors 325 and 326 of the buffer stage 320 serve as DC blocking capacitors, and further serve to provide negative feedback for the common-gate amplifiers to reduce the input impedance of the current buffer.

In the exemplary embodiment shown in FIG. 3, the third transistor 323 and the fourth transistor 324 (attenuation transistors 323 and 324) comprise variable elements (as schematically illustrated by the slanted arrows across the transistors) which are utilized to adjust the signal amplitude in the complementary output signal paths. The third transistor 323 is coupled in parallel with the first transistor 321 in the first signal path, and the fourth transistor 324 is coupled in parallel with the second transistor 322 in the second signal path. The third transistor 323 and the fourth transistor 324 have respective gate terminals that are commonly coupled to a second bias voltage V_{BIAS2}. The third transistor 323 and the fourth transistor 324 have drain terminals that are commonly coupled to a fifth node n5. The fifth node n5 (or virtual AC ground node n5) is coupled to a fixed power supply node V_{DD} for biasing the drain terminals of the first, second, third, and fourth transistors 321, 322, 323, and 324. In addition, the fifth node n5 serves as a virtual AC ground node.

In some embodiments, the third transistor 323 and the fourth transistor 324 each comprises a variable-width transistor that is structurally configured and digitally controlled (via s first control signal C1) using known techniques to vary an effective gate width of the transistor structure. For example, in some embodiments, the third transistor 323 and the fourth transistor 324 are structurally configured to include a plurality of transistor segments that are coupled in parallel, wherein the number of segments that are active/inactive at a given time (via the digital control signal C1) can be adjusted to change the effective gate width of the transistor. In this regard, the effective widths of the third transistor 323 and the fourth transistor 324 can be configured to adjust an amount of signal attenuation in the first and second signal paths.

In particular, to obtain a maximum output signal amplitude (maximum current output) from the buffer stage 320, the third transistor 323 and the fourth transistor 324 can be deactivated by setting the second bias voltage V_{BIAS2} to zero volts (OV). In this case, all of the first current signal

$${S}_{IN}^{+}$$

will flow into the source terminal of the first transistor 321, and all of the second current signal

$${S}_{IN}^{-}$$

will flow into the source terminal of the second transistor 322. On the other hand, the third transistor 323 and the fourth transistor 324 can be activated by setting the second bias voltage V_{BIAS2} to desired DC voltage, non-zero volts (OV). In this case, some of the first current signal

$${S}_{IN}^{+}$$

will flow into the source terminal of the third transistor 323 and be shunted to the virtual AC node n5, and some of the second current signal

$${S}_{IN}^{-}$$

will flow into the source terminal of the fourth transistor 324 and be shunted to the virtual AC node n5.

In this regard, activating the third transistor 323 and the fourth transistor 324 results in the attenuation of the output signal amplitudes in the first and second signal paths, which are output from the buffer stage 320. The amount of attenuation of the output signal amplitude (i.e., scaling the output amplitudes) is tuned by digitally controlling the effective widths of the third and fourth transistors 323 and 324, whereby increasing the number of activated segments of the third and fourth transistors 323 and 324 results in increasing the attenuation level (decreasing the output signal amplitude) of the output signal amplitudes in the first and second signal paths, while decreasing the number of activated segments of the third and fourth transistors 323 and 324 results in decreasing the attenuation level of the output signal amplitudes (increasing the output signal amplitude) in the first and second signal paths.

In the resonant tank 330, the first inductor 331 and the second inductor 332 comprise a differential inductive impedance and are connected in parallel to the first output node n3 and the second output node n4. Similarly, the first variable capacitor 333 and the second variable capacitor 334 comprise a differential capacitive impedance and are connected in parallel to the first output node n3 and the second output node n4. In addition, the first inductor 331 and the first variable capacitor 333 are coupled in parallel between the first output node n3 and the virtual AC ground node n5. Similarly, the second inductor 332 and the second variable capacitor 334 are coupled in parallel between the second output node n4 and the virtual AC ground node n5. Further, the variable resistor 335 is connected to and between the first and second output nodes n3 and n4.

As schematically illustrated in FIG. 3, the first and second variable capacitors 333 and 334 are commonly controlled by a second control signal C2, and the variable resistor 335 is controlled by a third control signal C3. The input impedance of the buffer stage 320 can be tuned by varying the capacitance C of the first and second variable capacitors 333 and 334 (via the second control signal), and/or varying the resistance R of the variable resistor 335 (via the third control signal C3). In this regard, varying the R and/or C values of the resonant tank 330, which loads the first and second transistors 321 and 322 of the buffer stage 320, serves to adjust the real (resistance) component and the imaginary (reactance) component of the complex input impedance of the buffer stage 320. The first and second variable capacitors 333 and 334 can be implemented using known variable capacitor devices, structures, and techniques (e.g., voltage-controlled capacitors, MOSFET capacitors, varactors, etc.) which are suitable for the given application. In addition, the variable resistor 335 can be implemented using known variable resistance devices, structures, and techniques.

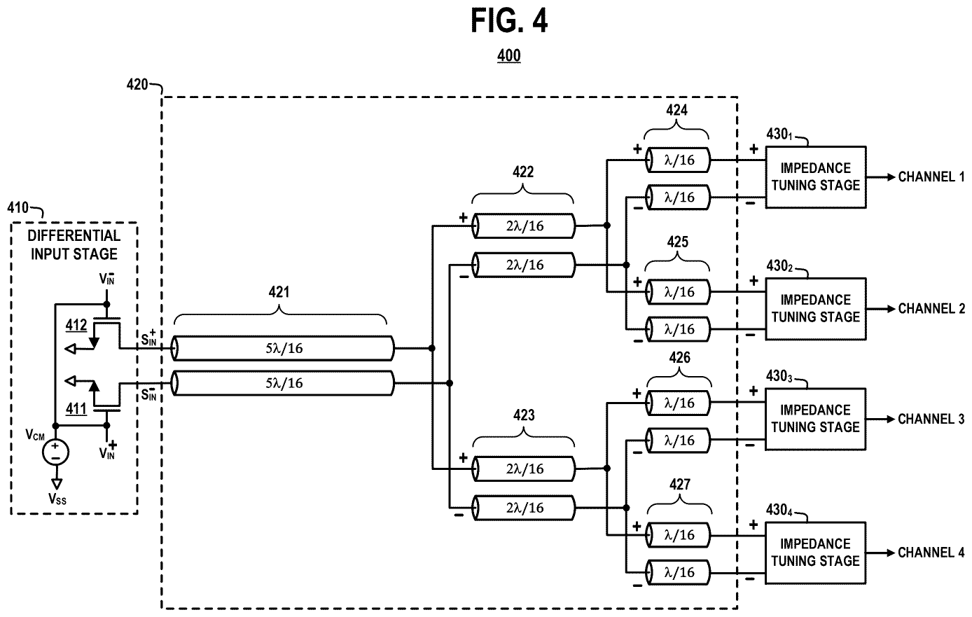

Next, FIG. 4 schematically illustrates a signal distribution network according to another exemplary embodiment of the disclosure. In particular, FIG. 4 schematically illustrates an exemplary embodiment of a signal distribution network 400 which comprises a differential input stage 410, a passive distribution network 420, and a plurality of impedance tuning stages 430₁, 430₂, 430₃, and 430₄. FIG. 4 illustrates an exemplary embodiment in which the signal distribution network 400 is configured to implement current mode distribution of complementary current signals

$${S}_{IN}^{+} and {S}_{IN}^{-}$$

over the passive distribution network 420. For example, in some embodiments, the differential input stage 410 comprises a pseudo differential transconductance amplifier which comprises a first transistor 411 and a second transistor 412. The first transistor 411 and the second transistor 412 comprise respective gate terminals which receive respective complementary voltage signals

$${V}_{IN}^{+} and {V}_{IN}^{-} ,$$

and which commonly receive as input a common mode voltage V_{CM}. For ease of illustration, drain biasing circuitry of the differential input stage 410 is not shown. The differential input stage 410 is configured to output complementary current signals

$${S}_{IN}^{+} and {S}_{IN}^{-}$$

in response to the complementary voltage signals

$${V}_{IN}^{+} and {V}_{IN}^{-} .$$

The passive distribution network 420 comprises an H-tree topology of passive transmission line segments 421, 422, and 423, which provides a 1:N fanout factor (with N=4) to distribute the complementary current signals

$${S}_{IN}^{+} and {S}_{IN}^{-}$$

from the differential input stage 410 over the passive distribution network 420 to the four impedance tuning stages 430₁, 430₂, 430₃, and 430₄ (output stages) and thus, to four signal channels Channel 1, Channel 2, Channel 3, and Channel 4, which are coupled to the outputs of the respective impedance tuning stages 430₁, 430₂, 430₃, and 430₄. In some embodiments, each impedance tuning stage 430₁, 430₂, 430₃, and 430₄ is implemented using the exemplary architecture of the impedance tuning stage 300 of FIG. 3. In some embodiments, as schematically illustrated in FIG. 4, the passive distribution network 420 is configured to provide a plurality of long transmission lines with electrical lengths that are one-half wavelength (λ/2), or a multiple n of one-half wavelengths (nλ/2) of the signal wavelength, to enable standing wave formation on the long transmission lines. For example, for transmission lines formed on silicon, the wavelength of a signal with a frequency of 10 GHz is approximately 7.5 millimeters.

As schematically illustrated in FIG. 4, the transmission line segment 421 comprises differential transmission lines having an electrical length of 5λ/16. The transmission line segment 421 branches (via a suitable branch transition structure) into two transmission line segments 422 and 423, where each transmission line segment 422 and 423 comprises differential transmission lines having an electrical length of 2λ/16. The transmission line segment 422 branches (via a suitable transition structure) into two transmission line segments 424 and 425, and the transmission line segment 423 branches (via a suitable branch transition structure) into two transmission line segments 426 and 427. The transmission line segments 424, 425, 426, and 427 each comprise differential transmission lines having an electrical length of λ/16. The transmission line segments 424, 425, 426, and 427 are coupled to the differential inputs of the respective impedance tuning stages 430₁, 430₂, 430₃, and 430₄.

In this exemplary embodiment, the transmission line segments 421, 422, and 424 are series coupled to provide a first transmission line path (of length λ/2) from the differential input stage 410 (source) to the first impedance tuning stage 430₁ (load). In addition, the transmission line segments 421, 422, and 425 are series coupled provide a second transmission line path (of length λ/2) from the differential input stage 410 (source) to the second impedance tuning stage 430₂ (load). Further, the transmission line segments 421, 423, and 426 are series coupled to provide a third transmission line path (of length λ/2) from the differential input stage 410 (source) to the third impedance tuning stage 430₃ (load). In addition, the transmission line segments 421, 423, and 427 are series coupled to provide a fourth transmission line path (of length λ/2) from the differential input stage 410 (source) to the fourth impedance tuning stage 430₄ (load). It is to be noted that while the transmission line paths can have the same electrical length λ/2, the physical lengths of the transmission lines paths can vary in embodiments, such as shown in FIG. 2B, where the passive distribution network 420 is configured to distribute signals with different frequencies to the signal channels.

It is to be noted that FIG. 4 illustrates a non-limiting exemplary of a passive distribution network 420 comprising an H-tree topology with a 1:4 fanout factor. However, in other exemplary embodiments of signal distribution networks, a passive distribution network can be implemented using an H-tree topology with any desired fanout factor, generally 1:N, where N denotes the number of impedance tuning stages (leaves of H-tree), and where N=d² where d denotes a depth of the H-tree structure. FIG. 4 illustrates an exemplary H-tree topology with a depth d=2.

Moreover, while FIG. 4 illustrates an exemplary H-tree topology in which the transmission line segments 421-427 are configured to provide transmission line paths from source to load with electrical lengths of λ/2 for an H-tree structure with depth d=2, it is to be understood that the respective electrical lengths of the transmission line segments will be distributed differently for H-tree topologies with different depths (e.g., d=1, d=3, etc.) to obtain overall electrical lengths of λ/2 (or multiples thereof) of the transmission line paths from source to load. Moreover, the electrical lengths of the transmission line segments for a given H-tree topology will vary depending on, e.g., the distance from source to load, the array fanout, the depth d of the H-tree, etc.

Furthermore, in some embodiments, the transmission line segments of a passive distribution network comprising a given H-tree topology can have fixed characteristic impedances Z₀. For example, in some embodiments, the transmission line segments 421-427 of the passive distribution network 420 of FIG. 4 can be designed to have fixed, nominally identical characteristic impedances (e.g., Z₀=50 Ohms). In such embodiments, the passive distribution network 420 has a fixed non-tunable impedance, and the input impedances that the passive transmission lines see at the inputs of the respective impedance tuning stages 430₁, 430₂, 430₃, and 430₄ are electronically tuned by, e.g., tuning the variable resistance and/or reactance components of the resonant tanks of the impedance tuning stages 430₁, 430₂, 430₃, and 430₄, as discussed above.

In other embodiments, at least some or all of the transmission line segments 421-427 of the passive distribution network 420 of FIG. 4 can be configured to have variable electrical lengths using suitable tuning mechanisms (e.g., slow wave structures). In particular, some or all of the transmission line segments 421-427 of the passive distribution network 420 can be digitally controlled to have tunable characteristic impedances or tunable delays, thereby implementing an additional impedance tuning mechanism for the exemplary signal distribution network 400. For example, the electrical length of a given transmission line segment can be tuned by adding shunt capacitances at several places along the physical length of the given transmission line to increase the capacitance of the given transmission line.

More specifically, in some embodiments, a set of metal lines can be positioned underneath a given transmission line segment. The metals lines are selectively connected or disconnected to and from a ground plane using respective arrays of transistor switches, which are controlled via a digital signal. When a given transistor switch is ON, the respective metal line is essentially connected to the ground plane and the given transmission line segment essentially sees a grounded metal line. On the other hand, when a given transistor switch is OFF, the respective metal line is not grounded, and the given transmission line segment essentially sees a shunt impedance (e.g., shunt capacitance), which changes the characteristics of the given transmission line segment. In this manner, the digital control signal is applied to the array of transistor switches to selectively adjust the number of metals lines that are grounded or not grounded, to change the amount of shunt capacitance that is applied to the given transmission line segment, and thereby tune the characteristic impedance and delay of the given transmission line segment.

It is to be appreciated that the exemplary signal distribution network 400 (and other exemplary signal distribution networks as discussed herein) is configured to enable low-power, and low-loss transmission of signals to a relatively large array of signal channels over long transmission line paths. For example, the implementation of the passive distribution network 420 with low-loss passive transmission lines allow for power-efficient distribution of current or voltage signals with low power dissipation, low signal distortion (e.g., low harmonic distortion). In particular, for quantum computing applications, the transmission lines of the passive distribution network 420 are formed of a superconducting metal material (e.g., niobium (Nb), etc.) and are disposed in a cryogenic temperature environment, thereby providing extremely low loss and low power dissipation.

In addition, the passive transmission lines of the passive distribution network 420 do not implement active devices (e.g., buffers) for signal transmission, which would add out-of-band noise and increase the noise floor of the signal transmission. For example, conventional signal distribution systems (for transmission of low frequency signals to mmWave frequency signals) implement long transmission lines by cascading a series of multiple transmission line segments and active buffers (e.g., CMOS inverters) which serve as signal repeaters to boost the signal transmission, wherein an active buffer is disposed between adjacent transmission line segments. The use of cascaded active buffers to implement long transmission lines is undesirable as the active buffers consume high power, and can inject noise into the signal path. Moreover, the use of active buffers provides a limited ability to reduce power consumption by reducing the supply voltage, but at the expense of increasing jitter, which is undesirable.

Moreover, the use of passive transmission line segments enables the transmission of clock signals and narrowband modulated radio frequency signals, wherein the distribution of such signals using passive transmission lines is efficient in terms of power consumption as the driver(s) of the input stage can be substantially linear and/or operate with less bandwidth. Furthermore, as noted above, the use of passive transmission line segments to implement the passive distribution network 420 enables wideband transmission of signals with different frequencies (e.g., FIG. 2B) and with low complexity. Indeed, the transmission line segments can be fabricated as desired to provide wideband performance, with no restriction terms of area, line width, line length, characteristic impedance, etc., while the multi-dimensional impedance tuning is implemented using the impedance tuning output stages (loads) to provide the desired load input impedances, which are seen by the outputs of the passive distribution network 420, to obtain the desired signal transfer characteristics, e.g., maximum power transfer from source to load, maximum voltage transfer from source to load, maximum current transfer from source to load, etc.

FIG. 5 schematically illustrates a peak detector which can be implemented in a signal distribution system, according to an exemplary embodiment of the disclosure. In particular, FIG. 5 schematically illustrates a multi-phase peak detector circuit 500 which can be utilized for amplitude detection of differential output signal, according to an exemplary embodiment of the disclosure. The multi-phase peak detector circuit 500 comprises a first transistor 501 and a second transistor 502, a current bias source 503, and a capacitor 504 which is coupled to and between an output node N_{OUT} and ground. The first transistor 501 and the second transistor 502 have a common-drain configuration wherein (i) drain terminals of the first transistor 501 and the second transistor 502 are connected to a fixed voltage V_{DD}, (ii) gate terminals of the first transistor 501 and the second transistor 502 are configured to receive differential input signals

$${V}_{IN}^{+} and {V}_{IN}^{-} ,$$

and wherein (iii) source terminals of the first transistor 501 and the second transistor 502 are commonly coupled to the output node N_{OUT}.

In an exemplary embodiment, the multi-phase peak detector circuit 500 can be coupled to the output of the impedance tuning stage 300 as shown in FIG. 3, wherein the output nodes n3 and n4 are coupled to the respective gate terminals of the first and second transistors 501 and 502, wherein the first output signal

$${S}_{OUT}^{+}$$

is applied to the gate terminal of the first transistor 501, and the second output signal

$${S}_{OUT}^{-}$$

is applied to the gate terminal of the second transistor 502. In this exemplary configuration, the first transistor 501 operates to charge the capacitor 504 to a peak amplitude of the first output signal

$${S}_{OUT}^{+}$$

during positive half-cycles of first output signal

$${S}_{OUT}^{+} ,$$

while the second transistor 502 operates to charge the capacitor 504 to a peak amplitude of the second output signal

$${S}_{OUT}^{-}$$

during positive half-cycles of second output signal

$${S}_{OUT}^{-} .$$

In this regard, the multi-phase peak detector circuit 500 essentially operates like a full-wave rectifier circuit. The peak amplitude is represented as an output voltage V_{OUT} which is utilized to perform, e.g., calibration functions.

For example, in some embodiments, the multi-phase peak detector circuit 500 can be utilized to perform calibration functions to capture peak amplitude information that is utilized by a calibration system (e.g., calibration system 240, FIGS. 2A and 2B) to generate control signals for tuning the input impedance of a given impedance tuning stage and/or scaling the amplitude of differential output signals that are output from given impedance tuning stage. For example, when performing calibration functions, the multi-phase peak detector circuit 500 can be configured to have different operating modes. For example, in a first mode of operation, the first transistor 501 and the second transistor 502 are concurrently operated to detect a peak amplitude with both output signal phases

$${S}_{OUT}^{+} and {S}_{OUT}^{-}$$

applied to the multi-phase peak detector circuit 500. In the first mode of operation, the multi-phase peak detector circuit 500 is immune from duty cycle error. In a second mode of operation, the first transistor 501 can be operated alone with the second transistor 502 deactivated to thereby detect a peak amplitude of the positive output signal phase

$${S}_{OUT}^{+} .$$

In a third mode of operation, the second transistor 502 can be operated alone with the first transistor 501 deactivated to thereby detect a peak amplitude of the negative output signal phase

$${S}_{OUT}^{-} .$$

For calibration, peak amplitude information can be captured using each of the three modes of operation, and collectively utilized to generate control signals for impedance tuning.

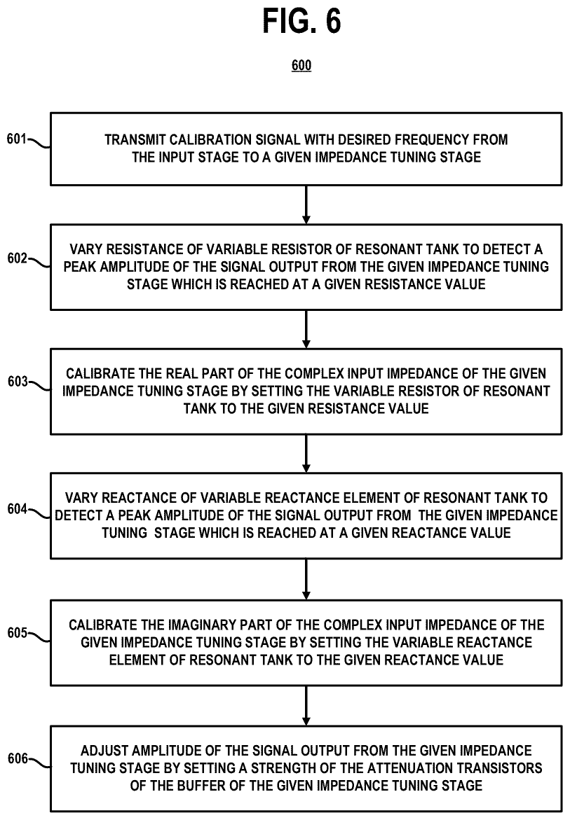

In some embodiments, a given impedance tuning stage having the exemplary architecture of the impedance tuning stage 300 of FIG. 3 can be calibrated using an exemplary calibration process. For example, FIG. 6 illustrates a flow diagram of a method 600 for calibrating an impedance tuning stage (e.g., the impedance tuning stage 300) of a signal distribution system, according to an exemplary embodiment of the disclosure. As an initial step, a calibration signal S_{IN} with a desired frequency is transmitted from source (input stage) to load (the given impedance tuning stage) (block 601). In some embodiments, the calibration signal can be a continuous signal that remains activated during the entire calibration process.

The variable resistor 335 of the resonant tank 330 is varied to detect (via a peak detector) a peak amplitude of the signal output from the given impedance tuning stage, which is reached at a given resistance value (block 602). The real part of the complex input impedance of the given impedance tuning stage is then calibrated by setting the resistance of the variable resistor 335 to the given resistance value which resulted in the peak amplitude (block 603). Next, the variable reactance element (e.g., first and second variable capacitors 333 and 334) of the resonant tank 330 is varied to detect (via a peak detector) a peak amplitude of the signal output from the given impedance tuning stage, which is reached at a given reactance (e.g., capacitance) value (block 604). The imaginary part of the complex input impedance of the given impedance tuning stage is then calibrated by setting the reactance (e.g., capacitance) of the first and second variable capacitors 333 and 334 of the resonant tank 330 to the given reactance value which resulted in the peak amplitude (block 605). Finally, with the input impedance of the given impedance tuning stage at the target complex impedance, the amplitude of the signal output from the given impedance tuning stage can be adjusted by setting a strength of the attenuation transistors 323 and 324 of the buffer stage 320 of the given impedance tuning stage (block 606).

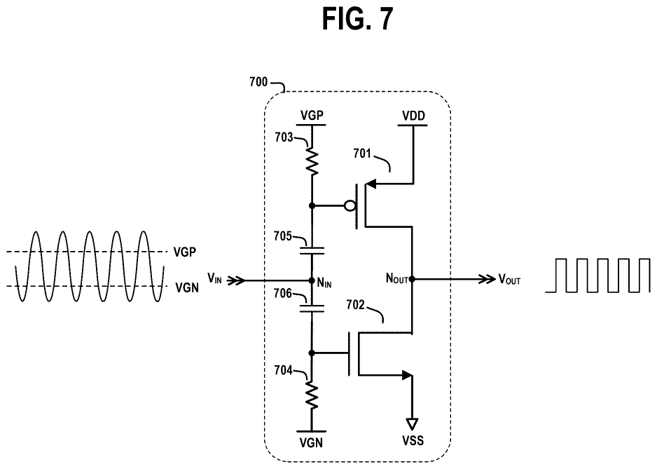

FIG. 7 schematically illustrates a buffer circuit which can be implemented in a signal channel of a multi-channel system, according to an exemplary embodiment of the disclosure. In particular, FIG. 7 schematically illustrates a buffer circuit 700 which can be utilized, for example, to implement the first buffers 131₁, . . . , 131_{N} of the signal channels 130₁, . . . , 130_{N} of the multi-channel system 100 of FIG. 1. The buffer circuit 700 comprises a split-biased inverter architecture which comprise a first transistor 701 (PMOS transistor), a second transistor 702 (NMOS transistor), a first resistor 703, a second resistor 704, a first capacitor 705, and a second capacitor 706. In addition, the buffer circuit 700 comprises an input node Nm, an output node N_{OUT}, a first voltage supply node which receives a first gate bias voltage VGP, and a second voltage supply node which receives a second gate bias voltage VGN.

As schematically shown in FIG. 7, the buffer circuit 700 is configured to convert a large amplitude sinusoidal waveform (V_{IN}) to a square pulse waveform (V_{OUT}). The buffer circuit 700 can be utilized to implement the first buffers 131₁, . . . , 131_{N} in embodiments where, e.g., the signal generator 110 is configured to generate a sinusoidal clock signal (S_{IN}), which is distributed over the signal distribution system 120 to the signal channels 130₁, . . . , 130_{N} of the multi-channel system 100, wherein each first buffer 131₁, . . . , 131_{N} converts a resulting sinusoidal clock signal (which is output from a respective impedance tuning stage) to a square wave clock signal to drive clocked components in the signal channels 130₁, . . . , 130_{N}. The transmission of the sinusoidal clock signal over the passive distribution network 122 consumes less energy as compared to transmitting a square wave clock signal over the passive distribution network 122. In this regard, the buffer circuit 700 allows sinusoidal clock signals to be transmitted over the passive distribution network 122 to minimize energy consumption (as compared to transmitting a square wave clock signal), while generating corresponding square wave clock signals to drive the signal channels 130₁, . . . , 130_{N}.

It is to be understood that in embodiments where the impedance tuning stages 123₁, . . . , 123_{N} in FIG. 1 are implemented using the exemplary circuit architecture of the impedance tuning stage 300 shown in FIG. 3, each first buffer 131₁, . . . , 131_{N} can include (i) a first instance of the buffer circuit 700 that is coupled to the output node n2 of impedance tuning stage 300 to receive the first output signal

$${S}_{OUT}^{+} ,$$

and (ii) a second instance of the buffer circuit 700 that is coupled to the output node n3 of the impedance tuning stage 300 to receive the second output signal

$${S}_{OUT}^{-} .$$

Moreover, each frequency divider 132₁, . . . , 132_{N} can include two nominally identical frequency dividers to frequency divide the differential output signals that are generated and output from the first and second instances of the buffer circuit 700.

It is to be appreciated that the exemplary signal distribution systems and networks as discussed herein can be readily implemented with various array-based systems that are utilized for commercial applications including, but not limited to, quantum computing systems, AI and ML systems, IoT systems, wireless communications systems, high-speed I/O systems, etc. For example, in some embodiments, the exemplary signal distribution systems and networks as discussed herein can be implemented in a quantum computing system to distribute signals that are utilized by CMOS circuitry to generate analog control pulses for controlling quantum devices, such as superconducting quantum bits, of a quantum processor (or quantum processing unit), and other types of quantum devices.

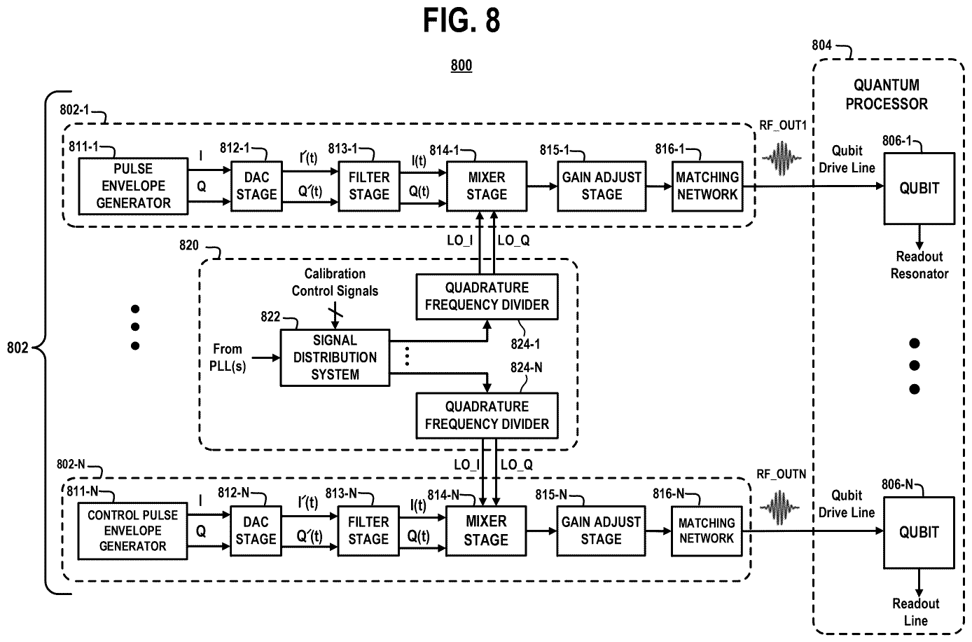

For example, FIG. 8 schematically illustrates a quantum computing system which implements a signal distribution system to distribute LO signals to a plurality of signal channels, according to an exemplary embodiment of the disclosure. In particular, FIG. 8 schematically illustrates a quantum computing system 800 which comprises an arbitrary waveform generator system 802 (or AWG system 802), a quantum processor 804, and an LO signal generation and distribution system 820. The quantum processor 804 comprises a plurality (N) of superconducting qubits 806-1, . . . , 806-N. The superconducting qubits 806-1, . . . , 806-N may comprise superconducting transmon qubits, superconducting fluxonium qubits, superconducting multi-mode qubits, and other types, or combinations of different types, of superconducting qubits, which are suitable for a given application.

The quantum processor 804 further comprises a plurality of control lines (e.g., transmission line resonators) including, but not limited to, qubit drive lines and readout resonators. In some embodiments, the qubit drive lines are coupled (e.g., capacitively coupled) to respective ones of the superconducting qubits 806-1, . . . 806-N. The qubit drive lines are configured to apply respective control pulses, RF_OUT1, . . . , RF_OUTN (which are generated by the AWG system 802) to the respective superconducting qubits 806-1, . . . , 806-N to change the states of the respective superconducting qubits (e.g., single-qubit gate operations), e.g., change the state of a given superconducting qubit to be in, e.g., a ground state |0 [symbol] , an excited state |1 [symbol] , or a superposition state. As is known in the art, the state of a superconducting qubit can be changed by applying a microwave control pulse with a center frequency that is equal to a transition frequency (denoted f₀₁) of the qubit, wherein the transition frequency f₀₁ corresponds to an energy difference between the ground state |0 [symbol] and excited state |1 [symbol] of the qubit. In some embodiments, the superconducting qubits 806-1, . . . , 806-N shown in FIG. 8 comprise a group of superconducting quantum bits (of a larger array of quantum bits) which are configured to have a same operating frequency (transition frequency). As is known in the art, neighboring superconducting qubits in a given lattice are designed to have transition frequencies which are detuned to minimize gate errors that can arise from lattice frequency collisions (e.g., improper detuning between superconducting qubits can reduce the fidelity of multi-qubit gate entanglement operations).

The readout resonators are coupled to respective ones of the superconducting qubits 806-1, . . . , 806-N to read the states of the superconducting qubits using known techniques (e.g., dispersive readout). In embodiments where the superconducting qubits comprise frequency-tunable qubits (e.g., flux-tunable transmon qubits or fluxonium qubits, etc.), flux bias control lines would be coupled (e.g., inductively coupled) to respective superconducting qubits to apply flux bias control signals to tuning structures of the superconducting qubits to tune the operating frequencies of the tunable qubits, as needed for a given application.

As shown in FIG. 8, the AWG system 802 comprises a multi-channel AWG framework which comprises a plurality of AWG channels 802-1, . . . , 802-N. As noted above, the AWG channels 802-1, . . . , 802-N are configured to generate respective control pulses, RF_OUT1, . . . , RF_OUTN, that are applied on the qubit drive lines to control respective ones of the superconducting qubits 806-1, . . . , 806-N. In some embodiments, the AWG channels 802-1, . . . , 802-N each comprise a respective control pulse envelope generator 811-1, . . . , 811-N, a respective digital-to-analog converter (DAC) stage 812-1, . . . , 812-N, a respective filter stage 813-1, . . . , 813-N, a respective mixer stage 814-1, . . . , 814-N, a respective gain adjust stage 815-1, . . . , 815-N, and a respective matching network 816-1, . . . , 816-N. In the exemplary embodiment shown in FIG. 8, the AWG system 802 implements a heterodyne I/Q modulation and mixing system which utilized quadrature signals (in-phase (I) and quadrature-phase (Q) signals) for performing I/Q modulation and up-conversion operations to thereby generate the respective control pulses, RF_OUT1, . . . , RF_OUTN.

The control pulse envelope generators 811-1, . . . , 811-N are configured to implement pulse-shaping techniques to generate baseband I/Q control pulses with desired control pulse envelope shapes (e.g., Gaussian pulses, cosine pulses (e.g., sum of half cosines), hyperbolic secant pulses, etc.), which are applied to superconducting qubits or active qubit coupler circuits to perform single qubit gate operations, entanglement gate operations, etc. The shaped control pulses are calibrated to drive f₀₁ transitions of the qubits, while suppressing f₁₂ and higher transitions. Essentially, such pulse shaping techniques suppress/reduce the transients associated with turning the control pulses on and off. In addition, pulse-shaping techniques include DRAG (derivative removal by adiabatic gate) correction pulses, which can be used in conjunction with shaped pulses (such as Gaussian pulses, cosine pulses, or hyperbolic secant pulses) to further suppress unwanted state transitions, while maintaining a same pulse envelope area (or integral of pulse envelope). As schematically shown in FIG. 8, the control pulse envelope generators 811-1, . . . , 811-N generate and output digital baseband pulse envelope signals (digital I and Q components).

In each AWG channel of the AWG system 802, the DAC stages 812-1, . . . , 812-N are configured to convert the digital baseband pulse envelope signals (digital I and Q components) to analog baseband pulse envelope signals I′ (t) and Q′ (t). The filter stages 813-1, . . . , 813-N, are configured to filter (e.g., low pass filter) the analog baseband pulse envelope signals I′ (t) and Q′ (t), and generate filtered analog baseband pulse envelope signals I(t) and Q(t). The mixer stages 814-1, . . . , 814-N are configured to perform mixing and up-conversion operations (e.g., via single-sideband (SSB) modulation) to modulate quadrature local oscillator signals LO_I and LO_Q (which are generated and output from the LO signal generation and distribution system 820) using the analog baseband pulse envelope signals I(t) and Q(t), to generate RF output signals. The gain adjusts stages 815-1, . . . , 815-N are configured to adjust the magnitude (e.g., attenuate) of the RF signals that are output from the mixer stages 814-1, . . . , 814-N. The matching networks 816-1, . . . , 816-N comprise impedance matching networks, as well as e.g., baluns to convert differential/balanced RF output signals from the gain adjust stages 815-1, . . . , 815-N to single-ended/unbalanced output signals, wherein the RF control pulses RF_OUT1, . . . RF_OUTN each comprise single-ended signals.

The LO signal generation and distribution system 820 comprises a signal distribution system 822, and a plurality of quadrature frequency dividers 824-1, . . . , 824-N. The signal distribution system 822 is implemented based on one or more of the exemplary architectures of the signal distribution systems and associated components (e.g., input stage, passive distribution network, and impedance tuning stages) as shown, for example, in FIGS. 1, 2A, 2B, 4, and 5. The signal distribution system 822 receives a clock signal from a PLL circuit, and distributes the clock signal to the quadrature frequency dividers 824-1, . . . , 824-N. The quadrature frequency dividers 824-1, . . . , 824-N convert the clock signal to quadrature LO signals LO_I and LO_Q, which are applied to LO inputs of the respective mixer stages 814-1, . . . , 814-N.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

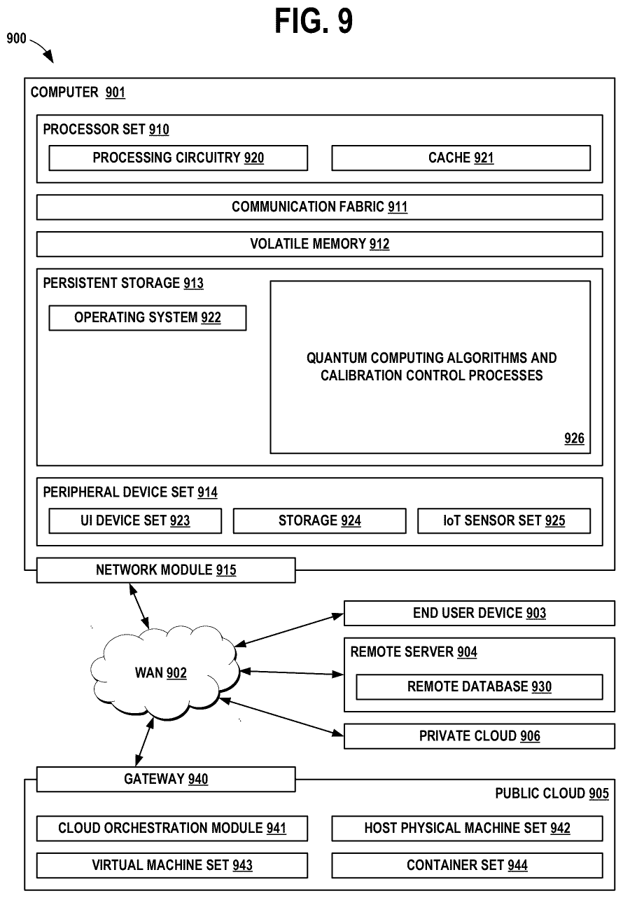

FIG. 9 schematically illustrates an exemplary computing environment 900 which is configured to execute program instructions for performing impedance tuning calibration operations for signal distribution, according to an exemplary embodiment of the disclosure. The computing environment 900 contains an example of an environment for the execution of at least some of the computer code 926 involved in performing various methods, such as quantum computing algorithm code to perform quantum computing or quantum information processing, and program code to perform calibration control processes (e.g., via the calibration system 240 of FIGS. 2A and 2B) to tune the complex input impedances of the impedance tuning stages as discussed above, as well as tune electrical lengths of passive transmission lines of the passive distribution networks, as discussed herein. In addition to block 926, computing environment 900 includes, for example, computer 901, wide area network (WAN) 902, end user device (EUD) 903, remote server 904, public cloud 905, and private cloud 906. In this embodiment, computer 901 includes processor set 910 (including processing circuitry 920 and cache 921), communication fabric 911, volatile memory 912, persistent storage 913 (including operating system 922 and block 926, as identified above), peripheral device set 914 (including user interface (UI), device set 923, storage 924, and Internet of Things (IoT) sensor set 925), and network module 915. Remote server 904 includes remote database 930. Public cloud 905 includes gateway 940, cloud orchestration module 941, host physical machine set 942, virtual machine set 943, and container set 944.

Computer 901 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 930. As is well understood in the art of computer technology, and depending upon the technology, performance of a computer-implemented method may be distributed among multiple computers and/or between multiple locations. On the other hand, in this presentation of computing environment 900, detailed discussion is focused on a single computer, specifically computer 901, to keep the presentation as simple as possible. Computer 901 may be located in a cloud, even though it is not shown in a cloud in FIG. 9. On the other hand, computer 901 is not required to be in a cloud except to any extent as may be affirmatively indicated.

Processor set 910 includes one, or more, computer processors of any type now known or to be developed in the future. Processing circuitry 920 may be distributed over multiple packages, for example, multiple, coordinated integrated circuit chips. Processing circuitry 920 may implement multiple processor threads and/or multiple processor cores. Cache 921 is memory that is located in the processor chip package(s) and is typically used for data or code that should be available for rapid access by the threads or cores running on processor set 910. Cache memories are typically organized into multiple levels depending upon relative proximity to the processing circuitry. Alternatively, some, or all, of the cache for the processor set may be located “off chip.” In some computing environments, processor set 910 may be designed for working with qubits and performing quantum computing.

Computer readable program instructions are typically loaded onto computer 901 to cause a series of operational steps to be performed by processor set 910 of computer 901 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 921 and the other storage media discussed below. The program instructions, and associated data, are accessed by processor set 910 to control and direct performance of the inventive methods. In computing environment 900, at least some of the instructions for performing the inventive methods may be stored in block 926 in persistent storage 913.

Communication fabric 911 is the signal conduction paths that allow the various components of computer 901 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 912 is any type of volatile memory now known or to be developed in the future. Examples include dynamic type random access memory (RAM) or static type RAM. Typically, the volatile memory is characterized by random access, but this is not required unless affirmatively indicated. In computer 901, the volatile memory 912 is located in a single package and is internal to computer 901, but, alternatively or additionally, the volatile memory may be distributed over multiple packages and/or located externally with respect to computer 901.

Persistent storage 913 is any form of non-volatile storage for computers that is now known or to be developed in the future. The non-volatility of this storage means that the stored data is maintained regardless of whether power is being supplied to computer 901 and/or directly to persistent storage 913. Persistent storage 913 may be a read only memory (ROM), but typically at least a portion of the persistent storage allows writing of data, deletion of data and re-writing of data. Some familiar forms of persistent storage include magnetic disks and solid-state storage devices. Operating system 922 may take several forms, such as various known proprietary operating systems or open-source Portable Operating System Interface type operating systems that employ a kernel. The code included in block 926 typically includes at least some of the computer code involved in performing the inventive methods.

Peripheral device set 914 includes the set of peripheral devices of computer 901. Data communication connections between the peripheral devices and the other components of computer 901 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 923 may include components such as a display screen, speaker, microphone, wearable devices (such as goggles and smart watches), keyboard, mouse, printer, touchpad, game controllers, and haptic devices. Storage 924 is external storage, such as an external hard drive, or insertable storage, such as an SD card. Storage 924 may be persistent and/or volatile. In some embodiments, storage 924 may take the form of a quantum computing storage device for storing data in the form of qubits. In embodiments where computer 901 is required to have a large amount of storage (for example, where computer 901 locally stores and manages a large database) then this storage may be provided by peripheral storage devices designed for storing very large amounts of data, such as a storage area network (SAN) that is shared by multiple, geographically distributed computers. IoT sensor set 925 is made up of sensors that can be used in Internet of Things applications. For example, one sensor may be a thermometer and another sensor may be a motion detector.

Network module 915 is the collection of computer software, hardware, and firmware that allows computer 901 to communicate with other computers through WAN 902. Network module 915 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 915 are performed on the same physical hardware device. In other embodiments (for example, embodiments that utilize software-defined networking (SDN)), the control functions and the forwarding functions of network module 915 are performed on physically separate devices, such that the control functions manage several different network hardware devices. Computer readable program instructions for performing the inventive methods can typically be downloaded to computer 901 from an external computer or external storage device through a network adapter card or network interface included in network module 915.

WAN 902 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 903 is any computer system that is used and controlled by an end user (for example, a customer of an enterprise that operates computer 901), and may take any of the forms discussed above in connection with computer 901. EUD 903 typically receives helpful and useful data from the operations of computer 901. For example, in a hypothetical case where computer 901 is designed to provide a recommendation to an end user, this recommendation would typically be communicated from network module 915 of computer 901 through WAN 902 to EUD 903. In this way, EUD 903 can display, or otherwise present, the recommendation to an end user. In some embodiments, EUD 903 may be a client device, such as thin client, heavy client, mainframe computer, desktop computer and so on.

Remote server 904 is any computer system that serves at least some data and/or functionality to computer 901. Remote server 904 may be controlled and used by the same entity that operates computer 901. Remote server 904 represents the machine(s) that collect and store helpful and useful data for use by other computers, such as computer 901. For example, in a hypothetical case where computer 901 is designed and programmed to provide a recommendation based on historical data, then this historical data may be provided to computer 901 from remote database 930 of remote server 904.

Public cloud 905 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 905 is performed by the computer hardware and/or software of cloud orchestration module 941. The computing resources provided by public cloud 905 are typically implemented by virtual computing environments that run on various computers making up the computers of host physical machine set 942, which is the universe of physical computers in and/or available to public cloud 905. The virtual computing environments (VCEs) typically take the form of virtual machines from virtual machine set 943 and/or containers from container set 944. It is understood that these VCEs may be stored as images and may be transferred among and between the various physical machine hosts, either as images or after instantiation of the VCE. Cloud orchestration module 941 manages the transfer and storage of images, deploys new instantiations of VCEs and manages active instantiations of VCE deployments. Gateway 940 is the collection of computer software, hardware, and firmware that allows public cloud 905 to communicate through WAN 902.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 906 is similar to public cloud 905, except that the computing resources are only available for use by a single enterprise. While private cloud 906 is depicted as being in communication with WAN 902, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 905 and private cloud 906 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
an input stage;
a signal distribution network comprising a plurality of passive elements; and
a plurality of output stages coupled to the signal distribution network;
wherein the input stage is configured to drive a signal onto the signal distribution network;
wherein the signal distribution network is configured to distribute the signal to the plurality of output stages; and
wherein each output stage of the plurality of output stages comprises a variable resistance element and a variable reactance element, for tuning a complex input impedance of the output stage to obtain a signal transfer characteristic for transferring the signal from the input stage to the output stage over the signal distribution network.

2. The device of claim 1, wherein the signal transfer characteristic comprises at least one of a maximum power transfer, a maximum voltage transfer, and a maximum current transfer.

3. The device of claim 1, wherein each output stage of the plurality of output stages comprises an attenuation circuit that is configured to scale an amplitude of the signal output from the output stage.

4. The device of claim 1, wherein each output stage of the plurality of output stages comprises:
a buffer circuit; and
a resonant tank circuit coupled to an output of the buffer circuit, wherein the resonant tank circuit comprises the variable resistance element and the variable reactance element for tuning the complex input impedance of the output stage.

5. The device of claim 4, wherein the variable reactance element comprises a variable capacitor.

6. The device of claim 4, wherein:
the signal is distributed in current mode over the signal distribution network; and
the buffer circuit comprises a current buffer which receives the signal as a current and outputs the signal as a current to the resonant tank circuit.

7. The device of claim 6, wherein the current buffer comprises:
a first transistor in a common gate amplifier configuration;
a second transistor connected in parallel with the first transistor;
the second transistor comprises an adjustable width transistor structure which comprises multiple transistor segments coupled in parallel; and
the width of the second transistor is adjusted in response to a control signal to scale an amplitude of the signal that is output from the current buffer to the resonant tank circuit.

8. The device of claim 1, wherein the input stage comprises:
a linear transconductance amplifier which is configured to receive a voltage signal and output a current signal as the signal to drive the signal distribution network; and
a programmable common mode input voltage.

9. The device of claim 1, wherein the signal distribution network comprises an H-tree topology of passive transmission lines which provide respective transmission line paths from the input stage to each output stage of the plurality of output stages.

10. The device of claim 9, wherein each transmission line path has an electrical length that is a multiple of one-half wavelength of wavelength of the signal that is distributed over the signal distribution network.

11. The device of claim 1, further comprising:
a peak detector circuit, coupled to at least one output stage of the plurality of output stages, and configured to detect one of: a maximum output power; maximum output voltage; and a maximum output current, of the at least one output stage; and
a calibration system coupled to the peak detector circuit, and configured to generate a control signal to tune the complex input impedance of the at least one output stage based at least in part on one of: the detected maximum output power; the detected maximum output voltage; and the detected maximum output current, of the at least one output stage.

12. A system, comprising:
a plurality of signal channels;
a signal generator which is configured to generate a signal; and
a signal distribution system which is configured to distribute the signal to the plurality of signal channels, wherein the signal distribution system comprises: an input stage; a signal distribution network comprising a plurality of passive elements; and a plurality of output stages; wherein:
each output stage is coupled to the signal distribution network and coupled to a respective signal channel of the plurality of signal channels;
the input stage is configured to drive the signal onto the signal distribution network;
the signal distribution network is configured to distribute the signal to the plurality of output stages; and
each output stage of the plurality of output stages comprises a variable resistance element and a variable reactance element, for tuning a complex input impedance of the output stage to obtain a signal transfer characteristic for transferring the signal from the input stage to the output stage over the signal distribution network.

13. The system of claim 12, wherein the signal transfer characteristic comprises at least one of a maximum power transfer, a maximum voltage transfer, and a maximum current transfer.

14. The system of claim 12, wherein each output stage of the plurality of output stages comprises:
a buffer circuit; and
a resonant tank circuit coupled to an output of the buffer circuit, wherein the resonant tank circuit comprises the variable resistance element and the variable reactance element for tuning the complex input impedance of the output stage.

15. The system of claim 14, wherein the variable reactance element comprises a variable capacitor.

16. The system of claim 14, wherein:
the signal is distributed in current mode over the signal distribution network; and
the buffer circuit comprises a current buffer which receives the signal as a current and outputs the signal as a current to the resonant tank circuit.

17. The system of claim 16, wherein the current buffer comprises:
a first transistor in a common gate amplifier configuration;
a second transistor connected in parallel with the first transistor;
the second transistor comprises an adjustable width transistor structure which comprises multiple transistor segments coupled in parallel; and
the width of the second transistor is adjusted in response to a control signal to scale an amplitude of the signal that is output from the current buffer to the resonant tank circuit.

18. A method, comprising:
driving, by an input stage, a signal onto a signal distribution network comprising a plurality of passive elements;
distributing the signal over the signal distribution network to a plurality of output stages; and
tuning a complex input impedance of a given output stage of the plurality of output stages by adjusting at least one of a variable resistance element and a variable reactance element of the given output stage to obtain a signal transfer characteristic for transferring the signal from the input stage to the given output stage over the signal distribution network.

19. The method of claim 18, wherein the signal transfer characteristic comprises at least one of a maximum power transfer, a maximum voltage transfer, and a maximum current transfer.

20. The method of claim 18, further comprising tuning an electrical length of at least one passive transmission line of the signal distribution network, in a transmission line path from the input stage to the given output stage, to obtain the signal transfer characteristic for transferring the signal from the input stage to the given output stage over the signal distribution network.
